(19) United States
(12) Patent Application Publication
(10) Pub. No.: US 2026/0327366 A1
(43) Pub. Date: Oct. 22, 2026

(54) FULLERENE-FUNCTIONALIZED (METH)ACRYLIC POLYMERS AND PREPARATION PROCESS THEREOF

(71) Applicant: ENI S.P.A., Roma (RM) (IT)

(72) Inventors: Paolo BIAGINI, Novara (NO) (IT); Riccardo PO', Novara (NO) (IT); Francesco GIACALONE, Palermo (PA) (IT); Carla CALABRESE, Palermo (PA) (IT)

(21) Appl. No.: 19/120,134

(22) PCT Filed: Oct. 10, 2023
(86) PCT No.: PCT/IB2023/060155

§ 371 Date: Apr. 10, 2025

(30) Foreign Application Priority Data
Oct. 11, 2022 (IT) 102022000020946

(51) Int. Cl. C08F 265/06; C08F 2/06; C08F 2/44; C08K 5/101; C08K 5/29; C08K 5/3432

(52) U.S. Cl. CPC C08F 265/06; C08F 2/06; C08F 2/44; C08K 5/101; C08K 5/29; C08K 5/3432

(57) ABSTRACT

Fullerene-functionalized (meth)acrylic polymer having formula (I):

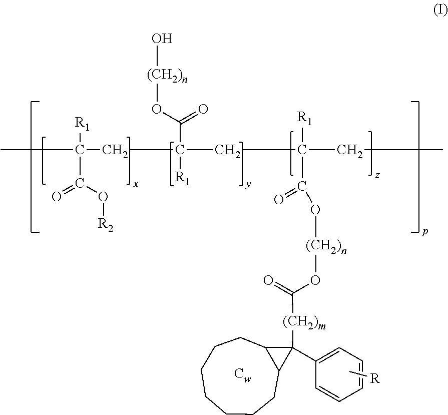

wherein:
x is a fractional number between 0 and 0.89;
y is a fractional number between 0.01 and 0.99;
z is a fractional number between 0.1 and 0.99;
provided that the sum of x+y+z is equal to 1;
p is an integer between 10 and 5000;
w is an integer between 50 and 250;
n and m, identical or different from each other, are an integer between 1 and 12;
R represents a hydrogen atom; or is selected from C₁-C₂₀, linear or branched, saturated or unsaturated, alkyl groups;
R₁, identical or different from each other, represent a hydrogen atom; or are selected from C₁-C₂₀, linear or branched, saturated or unsaturated alkyl groups;
R₂ represents a hydrogen atom; or is selected from C₁-C₂₀, linear or branched, saturated or unsaturated, alkyl groups.

### CROSS-REFERENCE TO RELATED APPLICATIONS

This application is a 35 U.S.C. § 371 National Stage patent application of PCT/IB2023/060155, filed on 10 Oct. 2023, which claims the benefit of Italian patent application 102022000020946, filed on 11 Oct. 2022, the disclosures of which are incorporated herein by reference in their entirety.

### TECHNICAL FIELD

The present disclosure relates to fullerene-functionalized (meth)acrylic polymers.

More specifically, the present disclosure relates to a fullerene-functionalized (meth)acrylic polymer having the specific general formula (I) hereinafter reported.

Said fullerene-functionalized (meth)acrylic polymer having general formula (I) can advantageously be used as an electron acceptor compound in organic photovoltaic devices (or solar devices) such as, for example, binary, ternary, quaternary, organic photovoltaic cells (or solar cells) having simple or “tandem” architecture, organic photovoltaic modules (or solar modules), on a rigid support or on a flexible support. Furthermore, said fullerene-functionalized (meth)acrylic polymer having general formula (I) can advantageously be used in perovskite-based photovoltaic cells (or solar cells) in the electron transport layer (ETL). Furthermore, said fullerene-functionalized (meth)acrylic polymer having general formula (I) can advantageously be used in the production of organic thin-film transistors (OTFTs), or organic field effect transistors (OFETs).

A further subject matter of the present disclosure is a process for the preparation of said fullerene-functionalized (meth)acrylic polymer having general formula (I).

The present disclosure also relates to an organic photovoltaic device (or solar device) such as, for example, an organic, binary, ternary, quaternary solar cell, having a simple or a “tandem” architecture, an organic photovoltaic module (or solar module), on a rigid support or on a flexible support, comprising at least one fullerene-functionalized (meth)acrylic polymer having the specific general formula (I).

The present disclosure also relates to a perovskite-based photovoltaic cell (or solar cell) wherein the electron transport layer (ETL) comprises at least one fullerene-functionalized (meth)acrylic polymer having the specific general formula (I).

The present disclosure also relates to organic thin-film transistors (OTFTs), or organic field-effect transistors (OFETs) comprising at least one fullerene-functionalized (meth)acrylic polymer having the specific general formula (I).

In the simplest way of operating, organic photovoltaic cells (or solar cells) are manufactured by introducing between two electrodes, usually consisting of indium-tin oxide (ITO) (anode) and aluminium (Al) (cathode), a photoactive thin layer (about 100 nanometres) of a mixture of an electron acceptor compound and an electron donor compound (an architecture known as “bulk heterojunction”). Generally, in order to make a layer of this type, a solution of the two compounds is prepared and, subsequently, a photoactive film is created on the anode [indium-tin oxide (ITO)] starting from said solution, using suitable deposition techniques such as, for example, “spin-coating”, “spray-coating”, “ink-jet printing”, and the like. Finally, the counter electrode [i.e. the aluminium cathode (Al)] is deposited on the dried film. Optionally, other additional layers can be introduced between the electrodes and the photoactive film, which layers are capable of performing specific functions of an electrical, optical, or mechanical nature.

Generally, in order to facilitate the achievement of the anode [indium-tin oxide (ITO)] by the electronic gaps (or holes) and at the same time to block the transport of electrons, thus improving the harvest of charges by the electrode and inhibiting the recombination phenomena, before creating the photoactive film starting from the mixture of the acceptor compound and the donor compound as described above, a film is deposited starting from an aqueous suspension of PEDOT:PSS [poly(3,4-ethylenedioxythiophene) polystyrene sulfonate], using suitable deposition techniques such as, for example, “spin-coating”, “spray-coating”, “ink-jet printing”, and the like.

In the vast majority of cases, the electron acceptor compound is selected from C₆₀, C₇₀ fullerene derivatives such as, for example, [6,6]-phenyl-C₆₁-butyric acid methyl ester (PC61BM), (6,6)-phenyl-C₇₁-butyric acid methyl ester (PC71BM). However, said fullerene derivatives show poor solubility in the solvents normally used for producing photovoltaic cells (or solar cells) and a certain tendency to segregate in the aforesaid photoactive layer.

One way to overcome the aforesaid drawbacks was to incorporate C₆₀ fullerene or C₇₀ fullerene into polymeric structures as reported, for example, by Giacalone F. et al. in “Chemical Reviews” (2006), Vol. 106, No. 12, pg. 5136-5190; Giacalone F. et al., in “Advanced Materials” (2010), Vol. 22, pg. 4220-4248.

Among the several attempts to incorporate fullerene into polymeric structures, mention must be made of the use of acrylates and methacrylates as basic macromolecules. Synthetic strategies for the preparation of fullerene-containing (meth)acrylic polymers are in such an advanced state that it is possible to synthesise a whole range of even highly complex structures by means of the most diverse polymerisation techniques: from the traditional radical polymerisation to the more sophisticated atom transfer radical polymerisation (ATRP). Thereby, (meth)acrylic copolymers containing random-type fullerene, or (meth)acrylic copolymers containing block-type fullerene, having high or low molecular weights and varying polydispersity indices, can be obtained.

The category of (meth)acrylic copolymers containing side-chain fullerene is one of the most studied. However, the most immediate strategy, i.e. the synthesis of fullerene-functionalized (meth)acrylic monomers and their subsequent co-polymerisation by the radical route does not lead to the desired polymers as reported, for example, by Mehrotra S. et al., in “Chemical Communications” (1997), pg. 463-464; Kirkwood K. et al., in “Journal of Polymer Science Part A: Polymer Chemistry” (1997), Vol. 35, Issue 15, pg. 3323-3325. The authors report, in fact, that during polymerisation, C₆₀ fullerene not only delays the polymerisation process but also undergoes multiple and random addition of radical chains, producing complex polymer mixtures that cannot be reproduced and are even partially cross-linked, which makes the obtained polymers insoluble and, therefore, which cannot be used for the purposes of the present disclosure.

Further examples of C₆₀ fullerene-functionalized poly(alkyl) methacrylates and poly(hydroxyalkyl) methacrylates are reported by Zheng J. et al. in “Polymer Bulletin” (1997), Vol. 39, pg. 79-84; Lu Z. H. et al., in “Polymer Bulletin” (1997), Vol. 39, pg. 661-667; Huang H. L. et al., in “Langmuir” (2003), Vol. 19, pg. 5332-5335; Goh H. W. et al., in “Journal of Polymer Science Part A: Polymer Chemistry” (2002), Vol. 40, Issue 8, pg. 1157-1166. The authors report the synthesis of copolymers containing different quantities of alkyl methacrylates such as, for example, methyl methacrylate, ethyl methacrylate, butyl methacrylate, or hydroxyalkyl methacrylates such as, for example, 2-hydroxyethyl methacrylate, 3-hydroxypropyl methacrylate, or 6-hydroxyhexyl methacrylate. Once the aforementioned methacrylate copolymers have been prepared, the hydroxyl groups are converted in two steps to azides, resulting in azido-polymers that can react with fullerene to give the desired C₆₀-functionalized methacrylate copolymers with a C₆₀ fullerene content between 0.6% by weight and 7.4% by weight. C₆₀-fullerene-functionalized methacrylate copolymers deriving from alkyl methacrylates are soluble in tetrahydrofuran (THF), chlorobenzene, or chloroform, while those deriving from hydroxyalkyl methacrylates are soluble in dimethylformamide (DMF), or methanol.

It should be noted, however, that the use of the aforesaid azido-polymers has the drawback that non-reacted azido groups can subsequently generate cross-linking processes that lead to materials that are not stable over time and cannot be processed and, therefore, cannot be used for the purposes of the present disclosure.

Sato H. et al., in “Polymer Bulletin” (2015), Vol. 72, No. 11, pg. 904-909, report the preparation of two different fullerene-containing methylacrylate monomers by the reaction of fullerene with 4-azidobenzoyloxyethyl methacrylate or with 4-azidobenzoyloxyethyl methacrylate. It is interesting to observe that the tests of subsequent anionic copolymerisation (with Grignard reagent) allow to obtain polymers with a low weight average molecular weight (M_{w}) but with a maximum of 10.5% by weight of C₆₀ fullerene, while radical polymerisation in the presence of α,α′-azo-isobutyronitrile (AIBN) as the radical initiator, fails, further confirming that the acrylic monomers of C₆₀ cannot be radically polymerised.

Ladelta V. et al., in “Polymer Journal” (1998), Vol. 30, pg. 1265-1280, report polymethyl methacrylates having a high C₆₀ fullerene content (i.e. up to 41.4% by weight) obtained by reaction, in chlorobenzene, of azide-containing copolymers derived from random copolymers of 6-chlorohexyl methacrylate and methyl methacrylate with C₆₀ fullerene, said polymethyl methacrylates being soluble in common organic solvents such as chloroform (CHCl₃), tetrahydrofuran (THF) and toluene. Size exclusion chromatography (SEC) shows that said polymethyl methacrylates form intra- and inter-molecular aggregations in chloroform (CHCl₃), presumably due to the strong interactions between the C₆₀ fullerene pendant groups, whereas they do not form them in tetrahydrofuran.

Tollan C. M. et al., in “New Journal of Chemistry” (2008), Vol. 32, pg. 1373-1378, report a method for the synthesis of acrylic polymers containing C₆₀ fullerene that first involves the synthesis of a monosubstituted C₆₀ fullerene (i.e. mono-fulleropyrrolidine) that is subsequently reacted with an acryloyl chloride/methyl acrylate copolymer. The amine group of mono-fulleropyrrolidine reacts with the acyl-chloride group of said copolymer to form an amide bond. Said method allowed to obtain an acrylic polymer containing 44% by weight of C₆₀ fullerene. However, as the authors point out, the presence of acyl chloride groups in the final polymer, due to an incomplete substitution with the fulleropyrrolidine reagent, makes these materials little stable over time due to the high reactivity of the acyl chloride groups with moisture in the air. This drawback results in a progressive cross-linking of the materials that makes them insoluble and therefore cannot be used for the purposes of the present disclosure, as highlighted by the authors for the polymer with the highest fullerene content (P4), which is already insoluble as soon as it is prepared.

Procedures for the synthesis of block copolymers containing an electron-donor block of poly-3-hexylthiophene (P3HT) and an electron acceptor block containing a C₆₀ fullerene-functionalized (meth)acrylic monomer were also developed.

For example, Lee J. U. et al., in “Journal of Materials Chemistry” (2009), Vol. 19, pg. 1483-1489, report the synthesis of a diblock copolymer (P3HT-b-C₆₀) based on poly-3-hexylthiophene (P3HT) and C₆₀fullerene. For this purpose, poly-3-hexylthiophene (P3HT) was first synthesised via Grignard metathesis polymerisation, and subsequently methyl methacrylate (MMA) and 2-hydroxyethyl methacrylate (HEMA) were copolymerised using as an atom transfer radical polymerisation (ATRP) macroninitiator, a terminally functionalized poly-3-hexylthiophene (P3HT) (for example, functionalized with bromine), obtaining a diblock copolymer [P3HT-b-P(MMA-r-HEMA)]. Subsequently, a fullerene derivative, for example, the methyl ester of [6,6]-phenyl-C₆₁-butyric acid (PC61BM), was chemically bonded to the second HEMA block of said diblock copolymer, obtaining a diblock copolymer (P3HT-b-C₆₀). Films containing said diblock copolymer (P3HT-b-C₆₀) are said to show a nanoscale phase separation and a total fluorescence “quenching”.

Yang C. et al., in “Journal of Materials Chemistry” (2009), Vol. 19, pg. 5416-5423, report the synthesis of a diblock copolymer [P3HT-b-P(StireneₓAcrylate_{y})-C₆₀] through a combination of living polymerisation and subsequent cycloaddition. The aforementioned diblock copolymer, either as such or in film form, is said to exhibit a nanofibrillar structure and, when used in quantities of 5% by weight in a mixture of P3HT:PCBM, is said to improve the performance of photovoltaic devices by about 35%.

Li J. et al., in “Journal of Materials Chemistry” (2009), Vol. 19, pg. 5416-5423, report the synthesis of polymethacrylate containing a high quantity of C₆₀ fullerene (up to an average of 78 units of C₆₀ per chain determined by UV-vis). For this purpose, a monoalkynyl fullerene functionalized starting from pure C₆₀ fullerene was prepared. Subsequently, methyl methacrylate and 6-azido-hexyl methacrylate were randomly copolymerised via RAFT polymerisation (“Reversible Addition Fragmentation Chain Transfer Polymerisation”) to obtain a copolymer that was reacted with said monoalkynyl-fullerene functionalized via a copper-mediated “click” reaction, obtaining the aforementioned polymethacrylate. The aforementioned polymethacrylate containing a high quantity of C₆₀ fullerene shows, both in solution and in silicon wafers, an interchain “self-aggregation” behaviour that strongly depends on the quantity of C₆₀ fullerene in the chain.

Biglova Y. N. et al, in “Russian Journal of Physical Chemistry B” (2017), Vol. 11, No. 2, pg. 324-329, report the copolymerisation and homopolymerisation of acrylate-containing fullerenes with vinyl monomers. Fullerene-containing copolymers are said to be easily soluble in common organic solvents, while fullerene-containing homopolymers could not be characterised due to the high cross-linking degree.

Kötteritzsch J. et al., in “Journal of Applied Polymer Science” (2018), Vol. 135, Issue 10, 45916, report self-healing polymeric materials consisting of poly(lauryl methacrylate) with anthracene units in the side chains to which C₆₀ fullerene and methyl ester of [6,6]-phenyl-C₆₁-butyric acid (PC61BM) were covalently, but reversibly, bonded. The bonds formed by cycloaddition [4+2] between anthracene units and C₆₀ fullerene are reversible and break and form anew at 40° C.-60° C. The use of differently substituted anthracene monomers made it possible to adjust the reactivity and the resulting mechanical properties.

However, although the fullerene derivatives known in the art have excellent chemical and physical characteristics for their use in organic photovoltaic devices (or solar devices), they may also involve various technical issues either during the preparation of said photovoltaic devices (or solar devices) or once used in said photovoltaic devices (or solar devices) (for example, in terms of performance thereof).

As mentioned above, a major drawback is their low solubility in non-toxic solvents and higher solubility in toxic solvents such as, for example, halogenated solvents or carbon disulphide (CS₂). Furthermore, in order to achieve good results in terms of performance of photovoltaic devices (or solar devices), significant quantities of fullerene derivatives must be dispersed within the photoactive layer.

Furthermore, due to the large surface area π-pi, fullerene derivatives have a tendency to segregate even in the solid state within said photoactive layer, causing a drastic reduction in the efficiency of photovoltaic devices (or solar devices) as crystallites of fullerene derivatives are formed limiting the photophysical processes underlying their operation.

Furthermore, the processes for preparing fullerene derivatives are often complex multistep processes not suitable for an industrial process. Furthermore, said processes often use halogenated solvents which, as mentioned above, are toxic and, therefore, not advisable for an industrial process.

The Applicant therefore addressed the problem of finding new fullerene derivatives capable of overcoming the aforesaid drawbacks, as well as a preparation process thereof.

The Applicant has now found a fullerene-functionalized (meth)acrylic polymer having the specific general formula (I) hereinafter reported, as well as a process for preparing it, that overcomes the aforesaid drawbacks.

Said fullerene-functionalized (meth)acrylic polymer having general formula (I) can advantageously be used as an electron acceptor compound in organic photovoltaic devices (or solar devices) selected from, for example, binary, ternary, quaternary, organic photovoltaic cells (or solar cells) having a simple or “tandem” architecture, organic photovoltaic modules (or solar modules), on a rigid support or on a flexible support. Furthermore, said fullerene-functionalized (meth)acrylic polymer having general formula (I) can advantageously be used in perovskite-based photovoltaic cells (or solar cells) in the electron transport layer (ETL). Furthermore, said fullerene-functionalized (meth)acrylic polymer having general formula (I) can advantageously be used in the production of organic thin-film transistors (OTFTs), or organic field effect transistors (OFETs).

Furthermore, said fullerene-functionalized (meth)acrylic polymer having general formula (I) has a good solubility, which ensures that the synthesis process does not lead to cross-linked materials. In particular, said fullerene-functionalized (meth)acrylic polymer having general formula (I), in addition to the typical solubility in halogenated solvents such as chloroform, chlorobenzene and dichlorobenzene, has a good solubility in tetrahydrofuran (THF), methyltetrahydrofuran (Me-THF), dimethylsulfoxide (DMSO), dioxane (i.e. a solubility equal to 30 mg/ml-40 mg/ml), i.e. in solvents considered as environmentally “green”. In this regard, it should be noted that both the vast majority of fullerene derivatives and C₆₀ fullerene show almost zero solubility in this type of solvents [i.e. tetrahydrofuran (THF), methyltetrahydrofuran (Me-THF), dimethylsulfoxide (DMSO), dioxane], so the fullerene-functionalized (meth)acrylic polymer having general formula (I) can be used within a photovoltaic device either conventionally, by depositing a layer from a solution of chlorobenzene or xylene in the same way as C₆₀ or C₇₀ fullerene derivatives are usually deposited, or in an unconventional manner, i.e. from solutions of solvents such as tetrahydrofuran (THF), methyltetrahydrofuran (Me-THF), dimethylsulfoxide (DMSO), dioxane, thus making it possible, for example, a co-deposition with perovskite precursors such as, for example, lead iodide (PbI₂) and methylammonium iodide (MeNH₃I).

Furthermore, said fullerene-functionalized (meth)acrylic polymer having general formula (I) can be obtained via a one-step process in the presence of non-halogenated solvents. Furthermore, it should be noted that this process allows to obtain fullerene-functionalized (meth)acrylic polymers having general formula (I) containing varying quantities of fullerene and hydroxyl (—OH) groups which are thus capable of creating layers compatible with both the hydrophobic and hydrophilic layers usually found in organic photovoltaic devices (or solar devices) or in perovskite-based photovoltaic cells (or solar cells).

The present disclosure therefore provides a fullerene-functionalized (meth)acrylic polymer having general formula (I):

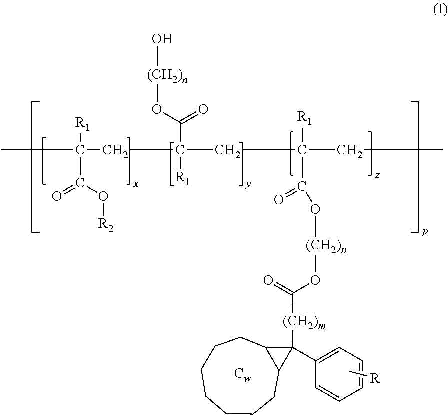

wherein:
x is a fractional number between 0 and 0.89, preferably between 0 and 0.6;
y is a fractional number between 0.01 and 0.9, preferably between 0.015 and 0.5;
z is a fractional number between 0.1 and 0.99, preferably between 0.25 and 0.95;
provided that the sum of x+y+z is equal to 1;
p is an integer between 10 and 5000, preferably between 20 and 2500;
w is an integer between 50 and 250, preferably between 60 and 90, more preferably is 60, 70, 84;
n and m, identical or different from each other, are an integer between 1 and 12, preferably between 2 and 6;
R represents a hydrogen atom; or is selected from C₁-C₂₀, preferably C₁-C₁₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups; preferably is hydrogen;
R₁, identical or different from each other, represent a hydrogen atom; or are selected from C₁-C₂₀, preferably C₁-C₁₀, linear or branched, saturated or unsaturated, alkyl groups, optionally containing heteroatoms, preferably are hydrogen or methyl;
R₂ represents a hydrogen atom; or is selected from C₁-C₂₀, preferably C₁-C₁₀, linear or branched, saturated or unsaturated, alkyl groups, optionally containing heteroatoms, preferably is methyl.

For the purpose of the present description and of the following claims, the definitions of the numerical intervals always comprise the extreme values unless otherwise specified.

For the purpose of the present description and of the following claims, the term “comprising” also includes the terms “which essentially consists of” or “which consists of”.

For the purpose of the present description and of the following claims, the term “C₁-C₂₀ alkyl groups” means linear or branched, saturated or unsaturated, alkyl groups having from 1 to 20 carbon atoms. Specific examples of C₁-C₂₀ alkyl groups are: methyl, ethyl, n-propyl, iso-propyl, n-butyl, iso-butyl, tert-butyl, pentyl, ethyl-hexyl, hexyl, heptyl, n-octyl, nonyl, decyl, dodecyl, 2-octyldodecyl, 2-ethyldodecyl, 2-butyloctyl, 2-hexyldecyl.

For the purpose of the present description and of the following claims, the term “C₁-C₂₀ alkyl groups optionally containing heteroatoms” means linear or branched, saturated or unsaturated, alkyl groups having from 1 to 20 carbon atoms, wherein at least one of the hydrogen atoms is substituted with a heteroatom selected from: halogens such as, for example, fluorine, chlorine, bromine, preferably fluorine; nitrogen; sulfur; oxygen. Specific examples of C₁-C₂₀ alkyl groups optionally containing heteroatoms are: fluoromethyl, difluoromethyl, trifluoromethyl, trichloromethyl, 2,2,2-trifluoroethyl, 2,2,2-trichlororoethyl, 2,2,3,3-tetrafluoropropyl, 2,2,3,3,3-pentafluoropropyl, perfluoropentyl, perfluoroctyl, perfluorodecyl, ethyl-2-methoxy, propyl-3-ethoxy, butyl-2-thiomethoxy, hexyl-4-amino, hexyl-3-N,N′-dimethylamino, methyl-N,N′-dioctylamino, 2-methyl-hexyl-4-amino.

For the purpose of the present description and of the following claims, the term “aryl groups” means aromatic carbocyclic groups containing from 6 to 60 carbon atoms. Said aryl groups can optionally be substituted with one or more groups, identical or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of aryl groups are: phenyl, methylphenyl, trimethylphenyl, methoxyphenyl, hydroxyphenyl, phenyloxyphenyl, fluorophenyl, pentafluorophenyl, chlorophenyl, bromophenyl, nitrophenyl, dimethylaminophenyl, naphthyl, phenylnaphthyl, phenanthrene, anthracene.

For the purpose of the present description and of the following claims, the term “heteroaryl groups” means heterocyclic aromatic, penta- or hexa-atomic groups, also benzocondensed or heterobicyclic, containing from 4 to 60 carbon atoms and from 1 to 4 heteroatoms selected from nitrogen, oxygen, sulfur, silicon, selenium, phosphorus. Said heteroaryl groups can optionally be substituted with one or more groups, identical or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of heteroaryl groups are: pyridine, methylpyridine, methoxypyridine, phenylpyridine, fluoropyridine, pyrimidine, pyridazine, pyrazine, triazine, tetrazine, quinoline, quinoxaline, quinazoline, furan, thiophene, hexylthiophene, bromothiophene, dibromothiophene, pyrrole, oxazole, thiazole, isothiazole, oxadiazole, tiadiazole, pyrazole, imidazole, triazole, tetrazole, indole, benzofuran, benzothiophene, benzooxazole, benzothiazole, benzooxadiazole, benzothiadiazole, benzopyrazole, benzimidazole, benzotriazole, triazolopyridine, triazolopyrimidine, coumarin.

For the purpose of the present description and of the following claims, the term “cycloalkyl groups” means cycloalkyl groups having from 3 to 30 carbon atoms. Said cycloalkyl groups can optionally be substituted with one or more groups, identical or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneox groups; cyan groups; amino groups; C₁-C₁₂ mono- or di-alkylamine groups; nitro groups. Specific examples of cycloalkyl groups are: cyclopropyl, 2,2-difluorocyclopropyl, cyclobutyl, cyclopentyl, cyclohexyl, methylcyclohexyl, methoxycyclohexyl, fluorocyclohexyl, phenylcyclohexyl, decalin, abietyl.

For the purpose of the present description and of the following claims, the term “heterocyclic groups” means rings having from 3 to 12 atoms, saturated or unsaturated, containing at least one heteroatom selected from nitrogen, oxygen, sulfur, silicon, selenium, phosphorus, optionally condensed with other aromatic or non-aromatic rings. Said heterocyclic groups can be optionally substituted with one or more groups, identical or different from each other, selected from: halogen atoms, such as fluorine, chlorine, bromine, preferably fluorine, hydroxyl groups, C₁-C₁₂ alkyl groups; C₁-C₁₂ alkoxy groups; C₁-C₁₂ thioalkoxy groups; C₃-C₂₄ polyethyleneoxy groups; cyano groups; amino groups; C₁-C₁₂ mono- or di-alkylamine groups; nitro groups. Specific examples of heterocyclic groups are: pyrrolidine, methoxypyrrolidine, piperidine, fluoropiperidine, methylpiperidine, dihydropyridine, piperazine, morpholine, thiazine, indoline, phenylindoline, 2-ketoazetidine, diketopiperazine, tetrahydrofuran, tetrahydrothiophene.

For the purpose of the present description and of the following claims, the term “C₁-C₂₀ dialkyl-amino groups” means groups comprising a nitrogen atom to which two C₁-C₁₂ alkyl groups are bonded. Specific examples of dialkyl-amino groups are: dimethylamine, diethylamine, dibutylamine, di-iso-butylamine.

For the purpose of the present description and of the following claims, the term “C₁-C₂₀ alkoxy groups” means groups comprising an oxygen atom to which a linear or branched, saturated or unsaturated, C₁-C₂₀ alkyl group is bonded. Specific examples of C₁-C₂₀ alkoxy groups are: methoxy, ethoxy, n-propoxy, iso-propoxy, n-butoxy, iso-butoxy, tert-butoxy, pentoxy, hexyloxy, heptyloxy, octyloxy, nonyloxy, decyloxy, dodecyloxy.

### SUMMARY

According to an embodiment of the present disclosure, said fullerene-functionalized (meth)acrylic polymer having general formula (I) has a fullerene content greater than or equal to 35% by weight, preferably between 40% by weight and 70% by weight, with respect to the total weight of said fullerene-functionalized (meth)acrylic polymer having general formula (I).

According to an embodiment of the present disclosure, said fullerene-functionalized (meth)acrylic polymer having general formula (I) has a content of hydroxyl groups (—OH) greater than or equal to 0.01% by weight, preferably between 0.05% by weight and 12% by weight, with respect to the total weight of said fullerene-functionalized (meth)acrylic polymer having general formula (I).

As mentioned above, the present disclosure also relates to a process for the preparation of said fullerene-functionalized (meth)acrylic polymer having general formula (I).

Accordingly, the present disclosure provides a process for the preparation of a fullerene-functionalized (meth)acrylic polymer having general formula (I) comprising reacting at least one (meth)acrylic polymer having general formula (II):

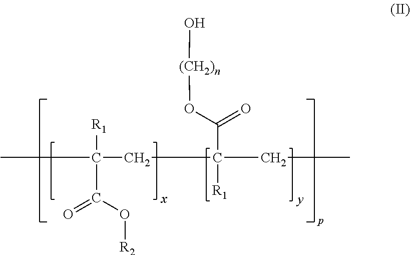

wherein:
x is a fractional number between 0 and 0.9, preferably between 0 and 0.6;
y is an integer or fractional number between 0.1 and 1, preferably between 0.15 and 1;
provided that the sum of x+y is equal to 1;
p is an integer between 10 and 5000, preferably between 20 and 2500;
n, R₁ and R₂, have the same meanings reported above;
   with at least one fullerene derivative having general formula (III):

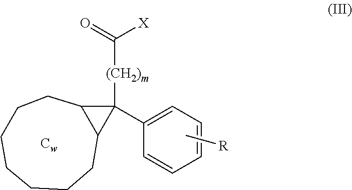

wherein m, R and w have the same meanings reported above and X represents a hydroxide anion, or a halide anion such as chloride, bromide, iodide, preferably a hydroxide anion or a chloride anion, more preferably a hydroxide anion; in the presence of:
an organic solvent or a mixture of organic solvents;
at least one substituted pyridine having general formula (IV):

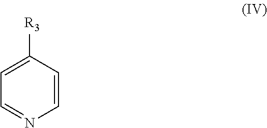

wherein R₃ represents a hydrogen atom; or is selected from C₁-C₂₀, preferably C₁-C₁₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups, C₁-C₂₀, preferably C₂-C₁₀, linear or branched, saturated or unsaturated, dialkyl-amino groups, C₁-C₂₀, preferably C₂-C₁₀, linear or branched, saturated or unsaturated, alkoxy groups; or represents an amino group, a cyano group, a hydroxyl group; preferably R₃ is methyl, tert-butyl, vinyl, dimethyl amino, methoxy, more preferably is dimethyl amino;
at least one substituted carbodiimide having general formula (V):

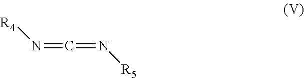

wherein R₄ and R₅, identical or different from each other, are selected from C₁-C₂₀, preferably C₁-C₁₀, linear or branched, saturated or unsaturated, alkyl groups, optionally containing heteroatoms, optionally substituted aryl groups, optionally substituted cycloalkyls, optionally substituted heterocyclic groups; preferably R₄ and R₅ are ethyl, iso-propyl, cyclohexyl, 3-dimethylamino propyl, more preferably are cyclohexyl.

According to an embodiment of the present disclosure, said organic solvent can be selected, for example, from dimethylsulphoxide (DMSO), xylene, toluene, mesitylene, tetrahydrofuran (THF), methyltetrahydrofuran (Me-THF), dioxane.

According to another embodiment of the present disclosure, said mixture of organic solvents is a mixture of organic solvents which may be selected, for example, from dimethylsulphoxide (DMSO), xylene, toluene, mesitylene, in a ratio 1/1 v/v, more preferably is a mixture of dimethylsulphoxide (DMSO)/toluene (1/1 v/v), dimethylsulphoxide (DMSO)/xylene (1/1 v/v).

According to another embodiment of the present disclosure, said (meth)acrylic polymer having general formula (II) and said fullerene derivative having general formula (III) may be used in a molar ratio with respect to the quantity in moles of the —OH groups contained in said (meth)acrylic polymer having general formula (II), between 10 and 0.1, preferably comprised between 5 and 0.25, even more preferably between 2.5 and 0.8.

According to another embodiment of the present disclosure said substituted pyridine having general formula (IV) can be selected, for example, from 4-dimethylaminopyridine (DMAP), 4-methylpyridine, 4-tert-butylpyridine, 4-vinylpyridine, 4-methoxypyridine, 4-hydroxypyridine or mixtures thereof; preferably it is 4-dimethylaminopyridine (DMAP).

According to a further embodiment of the present disclosure said carbodiimide having general formula (V) may be selected, for example, from N,N′-diethylcarbodiimide, N,N′-di-iso-propylcarbodiimide, N,N′-di-iso-propylcarbodiimide, N,N′-di-3-dimethylaminopropylcarbodiimide, N,N′-dicyclohexylcarbodiimide (DCC), or mixtures thereof; preferably N,N′-dicyclohexylcarboxydiimide (DCC).

According to an embodiment of the present disclosure, said substituted pyridine having general formula (IV) can be used in a molar ratio, with respect to the total moles of the fullerene derivative having general formula (III), between 0.9 and 0.1, preferably between 0.6 and 0.4.

According to a further embodiment of the present disclosure, said carbodiimide having general formula (V) can be used in a molar ratio, with respect to the total moles of the fullerene derivative having general formula (III), between 9 and 1, preferably between 6 and 4.

According to another embodiment of the present disclosure, said process can be carried out at a temperature between 15° C. and 150° C., preferably between 20° C. and 90° C.

According to an embodiment of the present disclosure, said process can be carried out for a time between 2 hours and 96 hours, preferably between 20 hours and 90 hours.

As mentioned above, said fullerene-functionalized (meth)acrylic polymer having general formula (I) can advantageously be used as an electron acceptorcompound in organic photovoltaic devices (or solar devices) such as, for example, binary, ternary, quaternary, organic photovoltaic cells (or solar cells) having simple or “tandem” architecture, organic photovoltaic modules (or solar modules), on a rigid support or on a flexible support. Furthermore, said fullerene-functionalized (meth)acrylic polymer having general formula (I) can advantageously be used in perovskite-based photovoltaic cells (or solar cells) in the electron transport layer (ETL). Furthermore, said fullerene-functionalized (meth)acrylic polymer having general formula (I) can advantageously be used in the production of organic thin-film transistors (OTFTs), or organic field effect transistors (OFETs).

Accordingly, the present disclosure further provides an organic photovoltaic device (or solar device) such as, for example, an organic, binary, ternary, quaternary solar cell, having a simple or “tandem” architecture, an organic photovoltaic module (or solar module), on a rigid support or on a flexible support, comprising at least one fullerene-functionalized (meth)acrylic polymer having the specific general formula (I).

The present disclosure further provides a perovskite-based photovoltaic cell (or solar cell) wherein the electron transport layer (ETL) comprises at least one fullerene-functionalized (meth)acrylic polymer having the specific general formula (I).

Also the present disclosure provides are organic thin film transistors (OTFTs), or organic field effect transistors (OFETs) comprising at least one fullerene-functionalized (meth)acrylic polymer having the specific general formula (I).

### DETAILED DESCRIPTION OF THE DISCLOSURE

In order to better understand the present disclosure and to put it into practice, some illustrative and non-limiting examples thereof are reported below.

The following characterisation methods were used in the following examples.

### NMR Spectra

The NMR spectra of the obtained compounds were carried out with a Bruker Avance 400 NMR spectrometer.

For this purpose, about 10 mg of the sample to be examined was dissolved in about 0.8 ml of a suitable deuterated solvent directly on the glass tube used for the measurement. The chemical shift scale was calibrated in relation to the tetramethylsilane signal set at 0 ppm.

### FT-IR Spectra

FT-IR spectra were recorded using Thermo Nicolet Nexus 670 and Bruker IFS 48 spectrophotometers.

FT-IR spectra of polymers were obtained from polymer films on potassium bromide (KBr) tablets, these films being obtained by deposition of a solution in warm 1,2-dichlorobenzene of the polymer to be analysed. The concentration of the polymer solutions analysed was 10% by weight with respect to the total weight of the polymer solution.

### Thermogravimetric Analysis (TGA)

The thermogravimetric analysis (TGA) was carried out using the TA Instruments® Q500 instrument by gradually increasing the temperature from 50° C. to 300° C. (at a rate of 20° C./minute), under nitrogen atmosphere, and continuously recording the weight variation of the sample.

### Example 1

### Preparation of the Copolymer P(MMA/HEMA) (CC334)

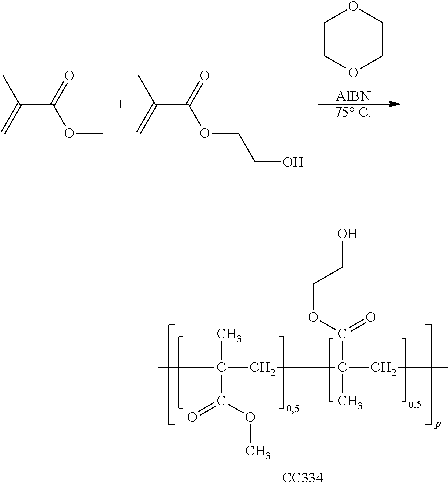

The synthesis of the copolymer P(MMA/HEMA) (CC334) was carried out by radical polymerisation of the monomers methyl methacrylate (MMA) (TCI Europe—purity>99.8%) and 2-hydroxyethyl methacrylate (HEMA) (TCI Europe—purity>95%). Said synthesis was carried out after purification of the monomers MMA and HEMA by filtration on neutral alumina (Merck) and using α,α′-azo-isobutyronitrile (AIBN) (Sigma Aldrich—purity>98%) recrystallised from methanol (MeOH) (VWR—purity>99.8%) as the radical initiator.

For this purpose, MMA (50 mmol), HEMA (50 mmol) and the radical initiator (AIBN) (0.3 mol %) were solubilised in 10.5 ml of 1,4-dioxane (Merck-purity>99%) in a 250 ml two-neck flask, equipped with a magnetic stirrer, in an inert atmosphere: the reaction mixture was kept, under stirring, at 75° C. for 16 hours. Subsequently, the temperature was allowed to drop spontaneously to room temperature (25° C.) and 50 ml of tetrahydrofuran (THF) [Merck—purity 99.9%-containing 250 ppm butylhydroxytoluene (BHT)] was added to the obtained reaction crude (colourless gel) until a homogeneous solution was obtained. Cold n-hexane (VWR—purity>95%) (100 ml) was added to the obtained homogeneous solution, resulting in the precipitation of a white solid. Said white solid was filtered, washed with cold n-hexane (VWR—95% purity) (3×20 ml) and dried in an oven at 60° C. overnight, resulting in 11.3 g of the copolymer P(MMA/HEMA) (CC334) (1:1 MMA/HEMA) corresponding to a yield of 98%.

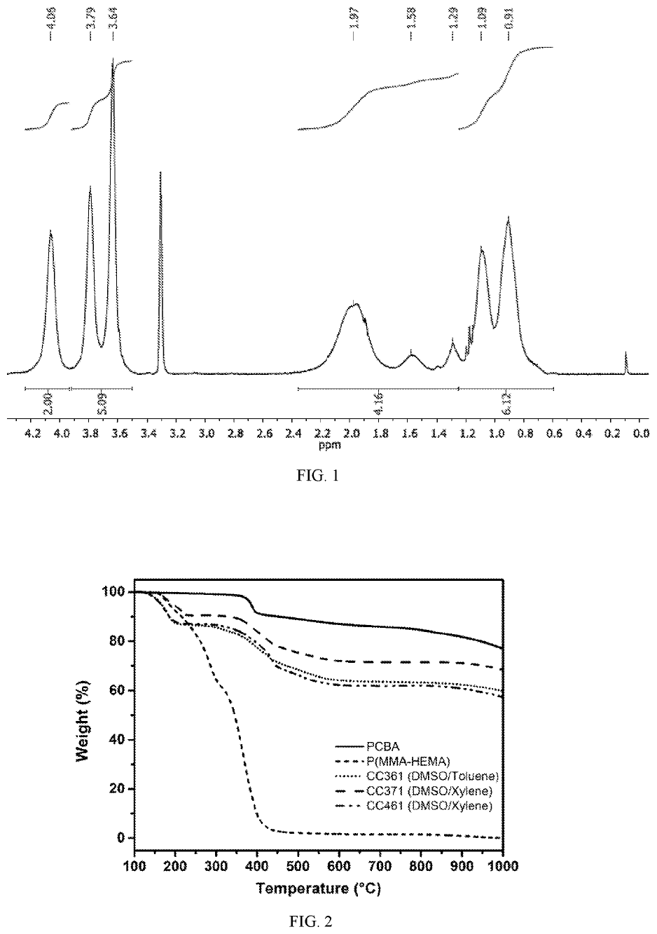

The copolymer P(MMA/HEMA) (CC334) was characterised by a 1H-NMR spectrum [400 MHz, in d⁴ methanol (VWR—purity 99.8%)], obtaining the spectrum shown in FIG. 1, from which it is confirmed that the two monomers are present in a 1:1 molar ratio: from this it was inferred that, with reference to the (meth)acrylic polymer having general formula (II), x=y=0.5.

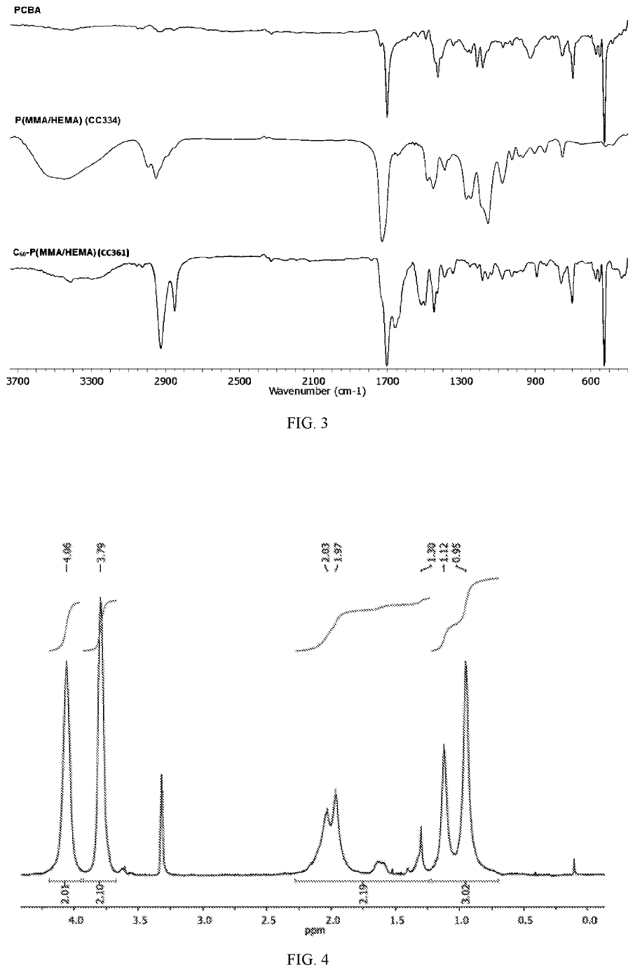

The copolymer P(MMA/HEMA) (CC334) was also characterised by thermogravimetric analysis (FIG. 2) and FT-IR spectroscopy (FIG. 3).

### Example 2

### Preparation of the Homopolymer PHEMA (CC344)

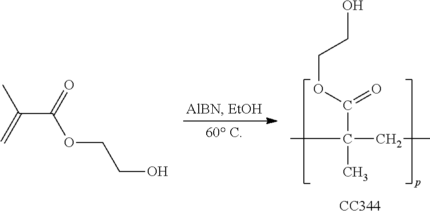

The synthesis of the homopolymer PHEMA (CC344) was carried out by radical polymerisation of the monomer 2-hydroxyethyl methacrylate (HEMA) (TCI Europe—purity>95%). Said synthesis was carried out after purification of the HEMA monomer by filtration on neutral alumina (Merck) and using α,α′-azo-isobutyronitrile (AIBN) (Sigma Aldrich—purity>98%) recrystallised from methanol (MeOH) (VWR—purity>99.8%) as the radical initiator.

For this purpose, HEMA (43 mmol) and the radical initiator (AIBN) (0.3 mol %) were solubilised in 15 ml of absolute ethanol (Merck) in a 250 ml two-neck flask, equipped with a magnetic stirrer, in an inert atmosphere: the reaction mixture was kept, under stirring, at 60° C. for 16 hours. Subsequently, the temperature was allowed to drop spontaneously to room temperature (25° C.) and cold n-hexane (VWR—purity>95%) (100 ml) was added to the obtained reaction mixture, resulting in the precipitation of a white solid. Said white solid was filtered, washed with cold n-hexane (VWR—purity 95%) (3×20 ml) and dried in an oven at 60° C. overnight, resulting in 5.3 g of the homopolymer PHEMA (CC344) corresponding to a yield of 95%. With reference to the (meth)acrylic polymer having general formula (II), it was inferred that x=0 and y=1.

The homopolymer PHEMA (CC344) was characterised by a 1H-NMR spectrum [400 MHz, in d⁴ methanol (VWR—purity 99.8%)], obtaining the spectrum shown in FIG. 4.

The homopolymer PHEMA (CC344) was also characterised by thermogravimetric analysis (FIG. 5).

### Example 3

### Preparation of the Fullerene Derivative PCBA

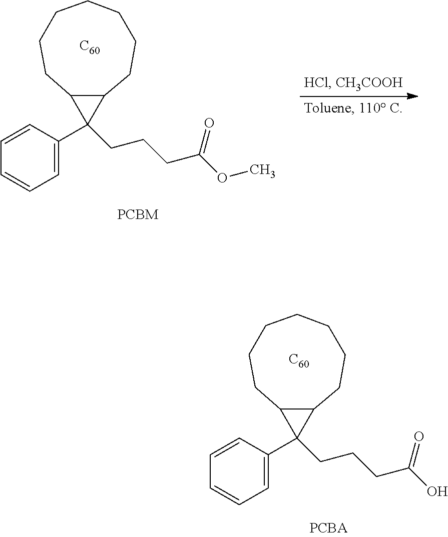 [SMILES: "C60" ; COC(=O)CCCC1(c2ccccc2)C2CCCCCCCC21 ; "C60" ; O=C(O)CCCC1(c2ccccc2)C2CCCCCCCC21]

The preparation of the fullerene derivative PCBA was carried out by hydrolysis of the methyl ester of [6,6]-phenyl-C₆₁-butyric acid (PC61BM) in toluene, according to the procedure reported by Hummelen J. C. et al. in “The Journal of Organic Chemistry” (1995), Vol. 60, pg. 532-538.

For this purpose, 56 ml of concentrated hydrochloric acid (HCl) (VWR-37% aqueous solution) and 139 ml of glacial acetic acid (Merck—purity>97%) were added to a solution of the methyl ester of [6,6]-phenyl-C₆₁-butyric acid (PC61BM) (2 g, 2.2 mmol) (Solenne BV—purity>99%) in 330 ml of toluene (VWR—purity>99.5%) in a 1-litre two-neck flask, equipped with a magnetic stirrer: the obtained reaction mixture was heated and kept at reflux, under stirring, for 48 hours. Subsequently, the temperature was allowed to drop spontaneously to room temperature (25° C.) and the solvent was removed by vacuum evaporation: the residue obtained was washed with diethyl ether (Merck—purity>99%) (3×10 ml), with toluene (Merck—purity>99%) (3×10 ml) and again with diethyl ether (Merck—purity>99%) (2×10 ml) and finally vacuum-dried, at room temperature (25° C.), for 6 hours, resulting in 1.85 g of the fullerene derivative PCBA corresponding to a yield of 94%.

The fullerene derivative PCBA was characterised by thermogravimetric analysis (FIG. 2) and FT-IR spectroscopy (FIG. 3).

### Example 4

### Preparation of the Fullerene-Functionalized Methacrylic Polymer C₆₀-P(MMA-HEMA) (CC361)

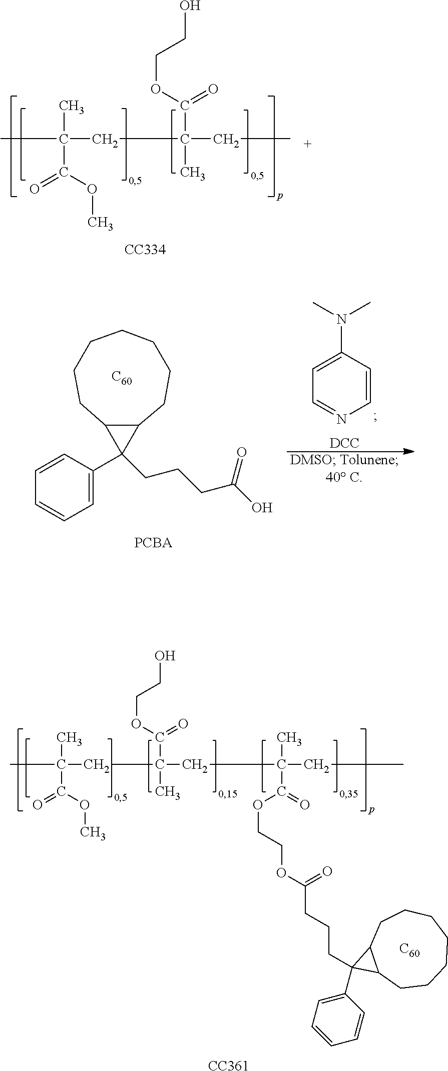

The incorporation of fullerene units into the copolymer P(MMA/HEMA) (CC334) for the preparation of the fullerene-functionalized methacrylic polymer C₆₀-P(MMA-HEMA) (CC361) was carried out as follows.

For this purpose, PCBA (275 mg, 0.304 mmol) obtained as described in Example 3, P(MMA/HEMA) (100 mg, 0.434 mmol of —OH groups) obtained as described in Example 1 and 4-dimethylaminopyridine (DMAP) (Merck—purity>99%) (0.16 mmol) were solubilised in 25 ml of a mixture of dimethyl sulfoxide (DMSO) (Merck—purity>99%)/toluene (VWR—purity>99.5%) (1:1, v/v) in a 100 ml two-neck flask, equipped with a magnetic stirrer, in an inert atmosphere. Subsequently, a solution of N,N′-dicyclohexylcarbodiimide (DCC) (Merck-purity 99%) (1.63 mmol) in 10 ml of a mixture of dimethylsulfoxide (DMSO) (Merck—purity>99%)/toluene (VWR—purity>99.5%) (1:1, v/v) was added dropwise to the reaction mixture. The obtained reaction mixture was kept, under stirring, at 40° C., in an inert atmosphere, for 72 hours. Subsequently, the temperature was allowed to drop spontaneously to room temperature (25° C.) and 50 ml of distilled water was added to the reaction mixture, resulting in two phases that were separated using a separating funnel, the aqueous phase was treated with toluene (VWR—purity>99.5%) (3×10 ml) and the organic phases obtained were joined to the former. Subsequently, the toluene was removed by vacuum evaporation at room temperature (25° C.). The solid residue obtained was treated with 25 ml of tetrahydrofuran (THF) [Merck—purity 99.9%-containing 250 ppm of butylhydroxytoluene (BHT) previously filtered over neutral alumina in order to remove the BHT present in the commercial product] in order to remove any non-reacted PCBA and the suspension obtained was kept, under stirring, at room temperature (25° C.), for 1 hour. Subsequently, the suspension was subjected to centrifugation and traces of insoluble material deposited at the bottom of the vessel were removed by settling. The resulting clear solution was concentrated, under vacuum, at room temperature (25° C.) to a volume of 5 ml and added dropwise to cold n-hexane (Merck—purity 95%) (100 ml), resulting in the precipitation of a brown solid. Said brown solid was recovered by vacuum filtration over a Buchner filter and washed over the filter with cold n-hexane (VWR—purity 95%) (2×20 ml), methanol (Merck) (2×15 ml) and diethyl ether (Merck, >99%) (2×10 ml) and finally dried in an oven at 60° C., overnight, resulting in 251 mg of the fullerene-functionalized methacrylic polymer C₆₀-P(MMA-HEMA) (CC361) corresponding to a yield of 68%.

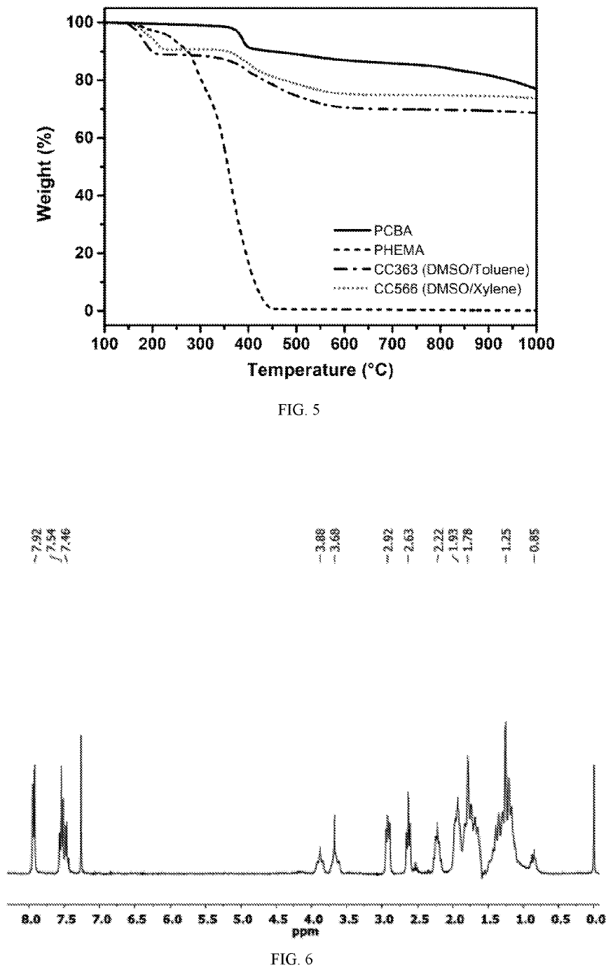

The fullerene-functionalized methacrylic polymer C₆₀-P(MMA-HEMA) (CC361) was characterised by 1H-NMR-spectrum [400 MHz, in d¹ chloroform (VWR—purity>99.8%),] obtaining the spectrum shown in FIG. 6.

The fullerene-functionalized methacrylic polymer C₆₀-P(MMA-HEMA) (CC361) was also characterised by thermogravimetric analysis (FIG. 2), from which it was possible to determine a residual fullerene content in the polymer equal to 60% by weight: from this data it was inferred that, with reference to the fullerene-functionalized methacrylic polymer having general formula (I), x=0.5, y=0.15 and z=0.35 while, from this data the content of —OH groups was calculated which was found to be equal to 0.6% by weight with respect to the total weight of said fullerene-functionalized (meth)acrylic polymer C₆₀-P(MMA-HEMA) (CC361).

The fullerene-functionalized methacrylic polymer C₆₀-P(MMA-HEMA) (CC361) was also characterised by IR spectroscopy (FIG. 3), wherein the presence of fullerene units in the polymer can be qualitatively confirmed by the presence of the absorption band at 525 cm⁻¹.

### Example 5

Preparation of the fullerene-functionalized methacrylic polymer C₆₀-P(MMA-HEMA) (CC461)

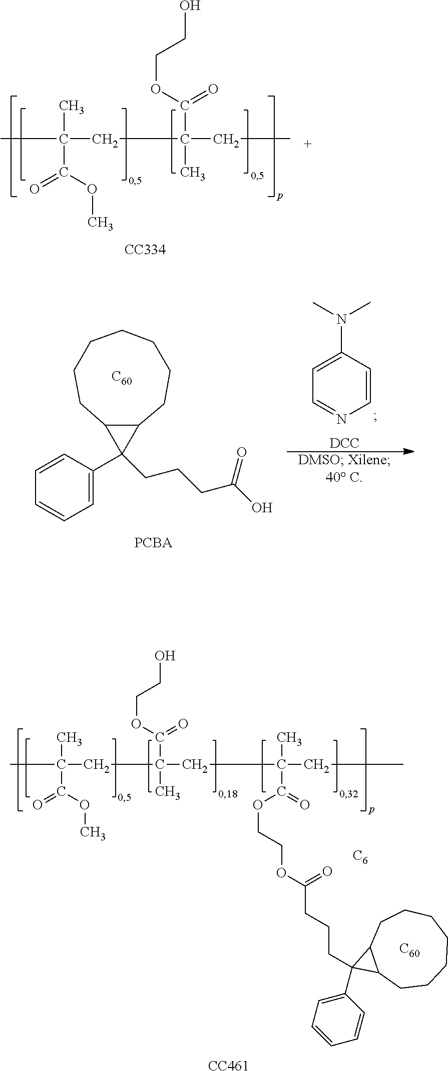

The incorporation of fullerene units into the copolymer P(MMA/HEMA) (CC334) for the preparation of the fullerene-functionalized methacrylic polymer C₆₀-P(MMA-HEMA) (CC461) was carried out as follows.

For this purpose, PCBA (253 mg, 0.282 mmol) obtained as described in Example 3, P(MMA/HEMA) (100 mg, 0.434 mmol of —OH groups) obtained as described in Example 1 and 4-dimethylaminopyridine (DMAP) (Merck—purity>99%) (0.16 mmol) were solubilised in 25 ml of a mixture of dimethyl sulfoxide (DMSO) (Merck—purity>99%)/xylene (Merck—purity>98%) (1:1, v/v) in a 100 ml two-neck flask, equipped with a magnetic stirrer, in an inert atmosphere. Subsequently, a solution of N,N′-dicyclohexylcarbodiimide (DCC) (Merck-99% purity) (1.63 mmol) in 10 ml of a dimethylsulfoxide (DMSO) (Merck->99% purity)/xylene (Merck->98% purity) mixture (1:1, v/v) was added dropwise to the reaction mixture. The obtained reaction mixture was kept, under stirring, at 40° C., in an inert atmosphere, for 72 hours. Subsequently, operating as described in Example 4, 225 mg of the fullerene-functionalized methacrylic polymer C₆₀-P(MMA-HEMA) (C₄₆₁) corresponding to a yield of 64% was obtained.

The fullerene-functionalized methacrylic polymer C₆₀-P(MMA-HEMA) (CC461) was characterised by thermogravimetric analysis (FIG. 2), from which it was possible to determine a residual fullerene content in the polymer equal to 58% by weight: from this data it was inferred that, with reference to the fullerene-functionalized (meth)acrylic polymer having general formula (I), x=0.5, y=0.18 and z=0.32, while, from this data the content of —OH groups was calculated which was found to be equal to 0.8% by weight with respect to the total weight of said fullerene-functionalized methacrylic polymer C₆₀-P(MMA-HEMA) (CC461).

### Example 6

### Preparation of the Fullerene-Functionalized Methacrylic Polymer C₆₀-P(MMA-HEMA) (CC371)

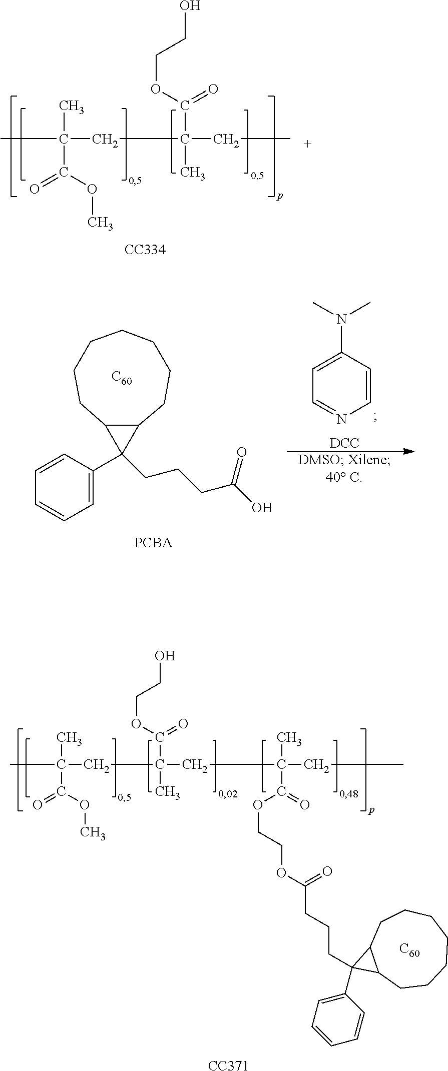

The incorporation of fullerene units into the copolymer P(MMA/HEMA) (CC334) for the preparation of the fullerene-functionalized methacrylic polymer C₆₀-P(MMA-HEMA) (CC371) was carried out as follows.

For this purpose, PCBA (214 mg, 0.239 mmol) obtained as described in Example 3, P(MMA/HEMA) (50 mg, 0.217 mmol of —OH groups) obtained as described in Example 1 and 4-dimethylaminopyridine (DMAP) (Merck—purity>99%) (0.14 mmol) were solubilised in 20 ml of a mixture of dimethyl sulfoxide (DMSO) (Merck—purity>99%)/xylene (Merck—purity>98%) (1:1, v/v) in a 100 ml two-neck flask, equipped with a magnetic stirrer, in an inert atmosphere. Subsequently, a solution of N,N′-dicyclohexylcarbodiimide (DCC) (Merck-99% purity) (1.38 mmol) was added dropwise to the reaction mixture in 20 ml of a mixture of dimethyl sulfoxide (DMSO) (Merck—>99% purity)/xylene (Merck—>98% purity) (1:1, v/v) and the obtained reaction mixture was kept at 40° C., under stirring, in an inert atmosphere, for 72 hours. Subsequently, operating as described in Example 4, 180 mg of the copolymer C₆₀-P(MMA/HEMA) (CC371) corresponding to a yield of 72% was obtained.

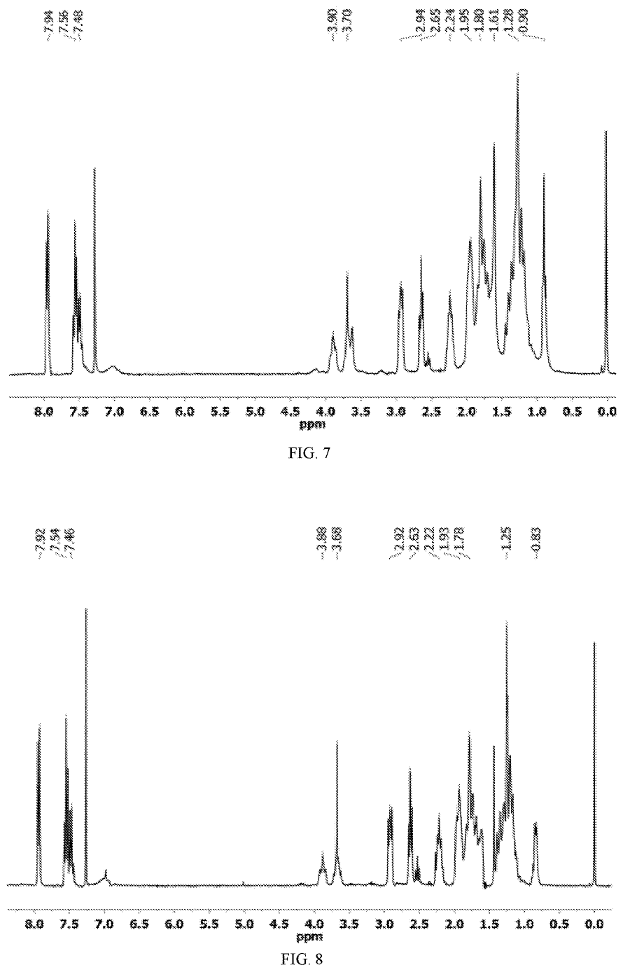

The fullerene-functionalized methacrylic polymer C₆₀-P(MMA-HEMA) (CC371) was characterised by 1H-NMR-spectrum [400 MHz, in d¹ chloroform (VWR—purity>99.8%),] obtaining the spectrum reported in FIG. 7.

The fullerene-functionalized methacrylic polymer C₆₀-P(MMA-HEMA) (CC371) was also characterised by thermogravimetric analysis (FIG. 2), from which a quantity of residual fullerene in the polymer equal to 64% by weight was determined: from this data it was inferred that, with reference to the fullerene-functionalized (meth)acrylic polymer having general formula (I), x=0.5, y=0.02 and z=0.48 while, from this data the content of —OH groups was calculated which was found to be equal to 0.06% by weight with respect to the total weight of said fullerene-functionalized methacrylic polymer C₆₀-P(MMA-HEMA) (CC371).

### Example 7

### Preparation of the Fullerene-Functionalized Methacrylic Polymer C₆₀-P(HEMA) (CC363)

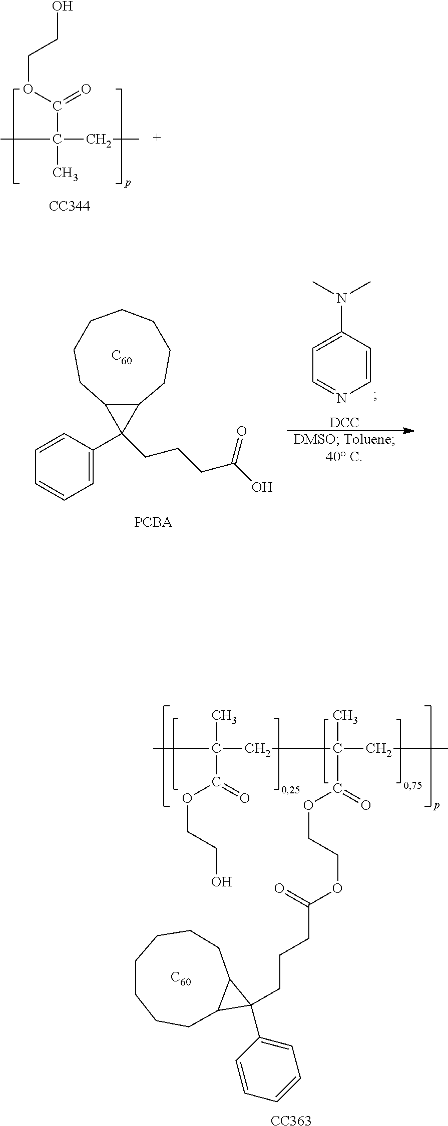

The incorporation of fullerene units into the polymer PHEMA (CC344) for the preparation of the fullerene-functionalized methacrylate polymer C₆₀-PHEMA (CC363) was carried out as follows.

For this purpose, PHEMA (100 mg, 0.768 mmol of —OH groups) obtained as described in Example 2 was dissolved in 15 ml of a mixture of dimethyl sulfoxide (DMSO) (Merck—purity>99%)/toluene (VWR—purity>99.5%) (1:1, v/v), in a 100 ml two-neck flask, equipped with a magnetic stirrer, in an inert atmosphere, keeping the mixture at 40° C., under stirring, for 14 hours. Subsequently, PCBA (517 mg, 0.576 mmol) obtained as described in Example 3, and 4-dimethylaminopyridine (DMAP) (Merck—purity>99%) (0.24 mmol) were added and, dropwise, a solution of N,N′-dicyclohexylcarbodiimide (DCC) (Merck—purity 99%) (2.41 mmol) in 10 ml of a mixture of dimethylsulfoxide (DMSO) (Merck—purity>99%)/toluene (VWR—purity>99.5%) (1:1, v/v): the obtained reaction mixture was kept, at 40° C., under stirring, in an inert atmosphere, for 72 hours. Subsequently, operating as described in Example 4, 394 mg of the copolymer C₆₀-PHEMA (CC363) corresponding to a yield of 65% was obtained.

The fullerene-functionalized methacrylic polymer C₆₀-PHEMA (CC363) was characterised by 1H-NMR spectrum [400 MHz, in d¹ chloroform (VWR-purity>99.8%),] obtaining the spectrum reported in FIG. 8.

The fullerene-functionalized methacrylic polymer C₆₀-PHEMA (CC363) was also characterised by thermogravimetric analysis (FIG. 5) from which it can be inferred that the quantity of residual fullerene in the polymer is 69% by weight: from this data it was inferred that, with reference to the fullerene-functionalized (meth)acrylic polymer having general formula (I), x=0, y=0.25 and z=0.75 while, from this data the content of —OH groups was calculated which was found to be equal to 0.5% by weight with respect to the total weight of said fullerene-functionalized (meth)acrylic polymer C₆₀-P(MMA-HEMA) (CC363).

### Example 8

### Preparation of the Fullerene-Functionalized Methacrylic Polymer C₆₀-PHEMA (CC566)

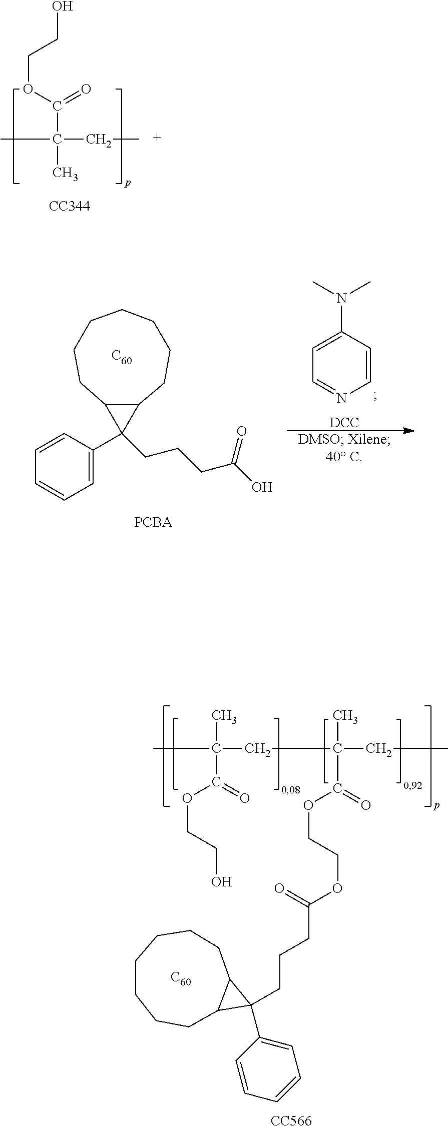

The incorporation of fullerene units into the copolymer PHEMA (CC344) for the preparation of the fullerene-functionalized methacrylic polymer C₆₀-PHEMA (CC566) was carried out as follows.

For this purpose, PHEMA (100 mg, 0.768 mmol of —OH groups) obtained as described in Example 2 was dissolved in 15 ml of a mixture of dimethylsulfoxide (DMSO) (Merck—purity>99%)/xylene (Merck—purity>98%) (1:1, v/v) in a 100 ml two-neck flask, equipped with a magnetic stirrer, in an inert atmosphere, keeping the mixture at 40° C., under stirring, for 14 hours. Subsequently, PCBA (633 mg, 0.706 mmol) obtained as described in Example 3, and 4-dimethylaminopyridine (DMAP) (Merck—purity>99%) (0.24 mmol) were added and, dropwise, a solution of N,N′-dicyclohexylcarbodiimide (DCC) (Merck—purity 99%) (2.41 mmol) in 10 ml of a mixture of dimethylsulfoxide (DMSO) (Merck—purity>99%)/xylene (Merck—purity>98%) (1:1, v/v): the obtained reaction mixture was kept, at 40° C., under stirring, in an inert atmosphere, for 72 hours. Subsequently, operating as described in Example 4, 540 mg of the fullerene-functionalized methacrylic polymer C₆₀-PHEMA (CC566) was obtained, corresponding to a yield of 75%.

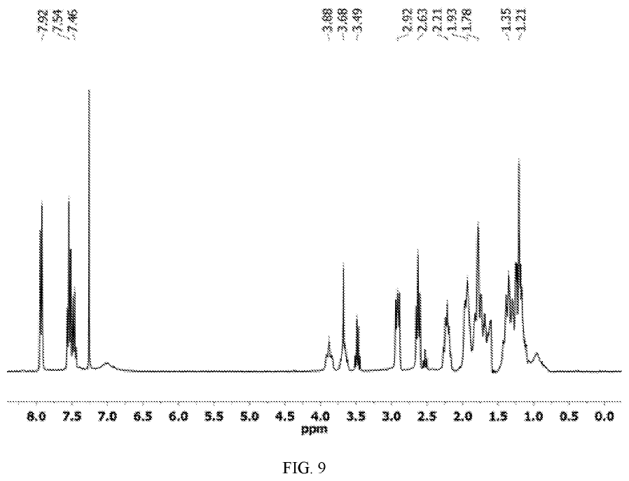

The fullerene-functionalized methacrylic polymer C₆₀-PHEMA (CC566) was characterised by 1H-NMR spectrum [400 MHz, in d¹ chloroform (VWR—purity>99.8%),] obtaining the spectrum reported in FIG. 9.

The fullerene-functionalized methacrylic polymer C₆₀-PHEMA (CC566) was also characterised by thermogravimetric analysis (FIG. 5), from which it was possible to determine a residual fullerene quantity in the polymer equal to 71% by weight: from this data it was inferred that, with reference to the fullerene-functionalized (meth)acrylic polymer having general formula (I), x=0, y=0.08 and z=0.92 while, from this data the content of —OH groups was calculated which was found to be equal to 0.14% by weight with respect to the total weight of said fullerene-functionalized methacrylic polymer C₆₀-P(MMA-HEMA) (CC566).

1. A fullerene-functionalized (meth)acrylic polymer having general formula (I): 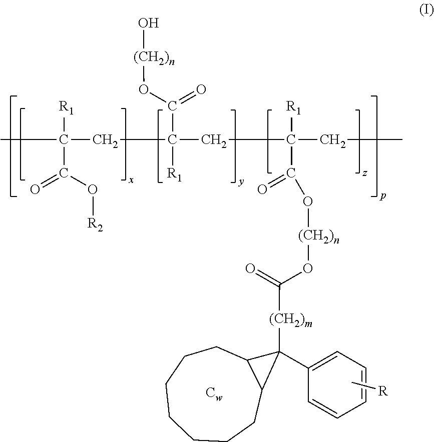
wherein:
x is a fractional number between 0 and 0.89;
y is a fractional number between 0.01 and 0.9;
z is a fractional number between 0.1 and 0.99;
provided that the sum of x+y+z is equal to 1;
p is an integer between 10 and 5000;
w is an integer between 50 and 250;
n and m, identical or different from each other, are an integer between 1 and 12;
R represents a hydrogen atom; or is selected from C₁-C₂₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups;
R₁, identical or different from each other, represent a hydrogen atom; or are selected from C₁-C₂₀, linear or branched, saturated or unsaturated, alkyl groups, optionally containing heteroatoms;
R₂ represents a hydrogen atom; or is selected from C₁-C₂₀, linear or branched, saturated or unsaturated, alkyl groups, optionally containing heteroatoms.

2. The fullerene-functionalized (meth)acrylic polymer having general formula (I) according to claim 1, wherein said fullerene-functionalized (meth)acrylic polymer having general formula (I) has a fullerene content greater than or equal to 35% by weight, with respect to the total weight of said fullerene-functionalized (meth)acrylic polymer having general formula (I).

3. The fullerene-functionalized (meth)acrylic polymer having general formula (I) according to claim 1, wherein said fullerene-functionalized (meth)acrylic polymer having general formula (I) has a content of hydroxyl groups (—OH) greater than or equal to 0.01% by weight, with respect to the total weight of said fullerene-functionalized (meth)acrylic polymer having general formula (I).

4. A process for preparing a fullerene-functionalized (meth)acrylic polymer having general formula (I) according to claim 1, comprising reacting at least one (meth)acrylic polymer having general formula (II): 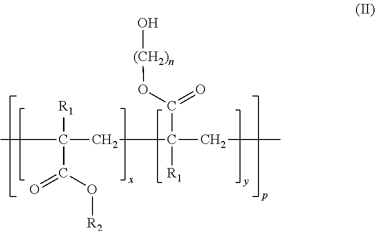
wherein:
x is a fractional number between 0 and 0.9;
y is an integer or fractional number between 0.1 and 1;
provided that the sum of x+y is equal to 1;
p is an integer between 10 and 5000;
n, R₁ and R₂, have the same meanings reported above;
with at least one fullerene derivative having general formula (III): 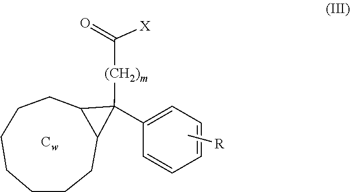
wherein m, R and w have the same meanings reported above and X represents a hydroxide anion, or a halide anion such as chloride, bromide, iodide;
in the presence of:
an organic solvent or a mixture of organic solvents;
at least one substituted pyridine having general formula (IV): 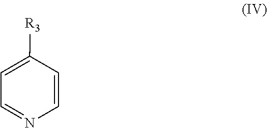
wherein R₃ represents a hydrogen atom; or is selected from C₁-C₂₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups, C₁-C₂₀, linear or branched, saturated or unsaturated, dialkyl-amino groups, C₁-C₂₀, linear or branched, saturated or unsaturated, alkoxy groups; or represents an amino group, a cyano group, a hydroxyl group;
at least one substituted carbodiimide having general formula (V): 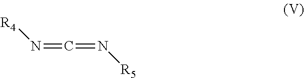
wherein R₄ and R₅, identical or different from each other, are selected from C₁-C₂₀, linear or branched, saturated or unsaturated, alkyl groups, optionally containing heteroatoms, optionally substituted aryl groups, optionally substituted cycloalkyls, optionally substituted heterocyclic groups.

5. The process for preparing a fullerene-functionalized (meth)acrylic polymer having general formula (I) according to claim 4, wherein said organic solvent is selected from dimethylsulfoxide (DMSO), xylene, toluene, mesitylene, tetrahydrofuran (THF), methyltetrahydrofuran (Me-THF), dioxane.

6. The process for preparing a fullerene-functionalized (meth)acrylic polymer having general formula (I) according to claim 4, wherein said mixture of organic solvents is a mixture of organic solvents which are selected from dimethyl sulfoxide (DMSO), xylene, toluene, mesitylene, in the ratio 1/1 v/v.

7. The process for preparing a fullerene-functionalized (meth)acrylic polymer having general formula (I) according to claim 4, wherein said (meth)acrylic polymer having general formula (II) and said fullerene derivative having general formula (III) are used in molar ratio with respect to the quantity in moles of the —OH groups contained in said (meth)acrylic polymer having general formula (II), between 10 and 0.1.

8. The process for preparing a fullerene-functionalized (meth)acrylic polymer having general formula (I) according to claim 4, wherein said substituted pyridine having general formula (IV) is selected from 4-dimethylaminopyridine (DMAP), 4-methylpyridine, 4-tert-butylpyridine, 4-vinylpyridine, 4-methoxypyridine, 4-hydroxypyridine or mixtures thereof.

9. The process for preparing a fullerene-functionalized (meth)acrylic polymer having general formula (I) according to claim 4, wherein said carbodiimide having general formula (V) is selected from N,N′-diethylcarbodiimide, N,N′-di-iso-propylcarbodiimide, N,N-di-3-dimethylaminopropylcarbodiimide, N,N-dicyclohexylcarbodiimide (DCC), or mixtures thereof.

10. The process for preparing a fullerene-functionalized (meth)acrylic polymer having general formula (I) according to claim 4, wherein said substituted pyridine having general formula (IV) is used in molar ratio, with respect to the total moles of the fullerene derivative having general formula (III), between 0.9 and 0.1.

11. The process for preparing a fullerene-functionalized (meth)acrylic polymer having general formula (I) according to claim 4, wherein said carbodiimide having general formula (V) is used in molar ratio, with respect to the total moles of the fullerene derivative having general formula (III), between 9 and 1.

12. The process for preparing a fullerene-functionalized (meth)acrylic polymer having general formula (I) according to claim 4, wherein said process is carried out:
at a temperature between 15° C. and 150° C.; and/or
for a time between 2 hours and 96 hours.

13. An organic photovoltaic device (or solar device) such as an organic, binary, ternary, quaternary solar cell, having simple or “tandem” architecture, an organic photovoltaic module (or solar module), on a rigid support or on a flexible support, comprising at least one fullerene-functionalized (meth)acrylic polymer having general formula (I) according to claim 1.

14. Perovskite-based photovoltaic (or solar cell) wherein the electron transport layer (ETL) comprises at least one fullerene-functionalized (meth)acrylic polymer having general formula (I) according to claim 1.

15. Organic thin film transistors (OTFTs), or organic field effect transistors OFETs) comprising at least one fullerene-functionalized (meth)acrylic polymer having general formula (I) according to claim 1.
